(19) United States
(12) Patent Application Publication
(10) Pub. No.: US 2009/0317548 A1
(43) Pub. Date: Dec. 24, 2009

(54) GAS TURBINE COMPONENT WITH A THERMAL BARRIER COATING, THERMAL BARRIER COATING FOR A GAS TURBINE COMPONENT AND PROCESS FOR PRODUCING A THERMAL BARRIER COATING ON A GAS TURBINE COMPONENT

(76) Inventor: Reinhold Meier, Dorfen (DE)

Correspondence Address: CROWELL & MORING LLP;INTELLECTUAL PROPERTY GROUP, P.O. BOX 14300, WASHINGTON, DC, 20044-4300, US

(21) Appl. No.: 12/376,271

(22) PCT Filed: Jul. 31, 2007
(86) PCT No.: PCT/DE2007/001360

§ 371 Date: Feb. 3, 2009

(30) Foreign Application Priority Data
Aug. 4, 2006 (DE) 10 2006 036 520.8

(51) Int. Cl. C23C 16/00

(52) U.S. Cl. 427/248.1

(57) ABSTRACT

A gas turbine component of an aircraft engine having a base body, which comprises at least a first material, and a thermal barrier coating that is applied to the base body and consists of or includes an oxide ceramic, is disclosed. Micro-defects and/or nano-defects are included in the oxide ceramic in order to reduce the thermal conductivity of the thermal barrier coating.

This application claims the priority of International Application No. PCT/DE2007/001360, filed Jul. 31, 2007, and German Patent Document No. 10 2006 036 520.8, filed Aug. 4, 2006, the disclosures of which are expressly incorporated by reference herein.

### BACKGROUND AND SUMMARY OF THE INVENTION

The invention relates to a gas turbine component having a thermal barrier coating, a thermal barrier coating for a gas turbine component as well as a process for producing a thermal barrier coating on a component, such as a gas turbine component.

The use of thermal barrier coatings on gas turbine components is already known from the field of aircraft engines. These types of thermal barrier coatings can consist for example of yttrium-stabilized ZrO₂. In order to reduce the thermal conductivity of these types of thermal barrier coatings, attempts were made, as known at least internally to the applicant, to modify the columnar structure, and namely, for example, in the direction of a herringbone structure or in the direction of diagonally growing columns. Nevertheless, there is a continued demand in the field of gas turbine components or aircraft engines for thermal barrier coatings with a good, even preferably improved, thermal barrier effect.

Accordingly, the invention is based on the objective of creating a good possibility for thermal insulation for gas turbine components.

### DESCRIPTION OF THE PREFERRED EMBODIMENTS

According to the invention, a gas turbine component having a base body, which comprises at least a first material, and a thermal barrier coating that is applied to the base body is provided. This thermal barrier coating consists of or includes an oxide ceramic. One or more micro-defects and/or nano-defects are incorporated into the oxide ceramic to reduce the thermal conductivity of the thermal barrier coating. These are generated in an advantageous embodiment within the scope of producing the thermal barrier coating in such a way that micro-defects and/or nano-defects are incorporated during or within the scope of the deposition process(es) of the oxide ceramic from the vapor phase in order to create a microporosity. In an advantageous embodiment, a microporosity is created in the process, which limits the free path of the gas or air molecule to one third.

According to an especially preferred embodiment, the thermal barrier coating features a non-porous top layer.

It may be provided that the deposition process of the oxide ceramic from the vapor phase and/or an injection of dry ice into the coating process or into the corresponding coating material take place in a PVD process, preferably in a high-rate PVD process with a Laure burner.

It may be provided that the dry ice is adapted in terms of size and quantity and/or with respect to the type of liquefied gas to the desired layer structure.

In an advantageous embodiment of the process, an essentially non-porous top layer of the thermal barrier coating is generated.

In an especially preferred embodiment, an inventive process or a further development of the inventive process is used to generate an inventive gas turbine component or a further development of an inventive gas turbine component. It may also be provided that an inventive thermal barrier coating or a further development of a thermal barrier coating is generated by means of an inventive process or a further development of the inventive process.

In the case of the respective designs of the invention, the component or gas turbine component may be, for example, a component for a gas turbine of an aircraft engine; it may be, for example, a high-pressure turbine guide vane (HPT guide vane) or a high-pressure turbine rotor blade (HPT rotor blade) or a combustion chamber liner of a gas turbine or of an aircraft engine.

In a preferred further development, the thermal barrier coating in the inventive designs is made of yttrium-stabilized ZrO₂, or includes yttrium-stabilized ZrO₂, or the oxide ceramic in the preferred further development is ZrO₂.

The invention lays the basis for various advantages, which may be given at least in the case of further developments of the invention. Thus, for example, a thermal barrier coating can be generated with improved thermal barrier effect while maintaining known physical properties. Furthermore, it is possible to enable the service life of components or gas turbine components provided with a thermal barrier coating to be extended with this type of improved layer or thermal barrier coating.

1. (canceled)

2. A process for producing a thermal barrier coating on a component, wherein the thermal barrier coating consists of or includes an oxide ceramic, and wherein the oxide ceramic is generated to form the thermal barrier coating on the component in a deposition process from a vapor phase:
wherein one or more defects from a group of defects, which includes a group of micro-defects and nano-defects, are incorporated into the oxide ceramic during the deposition process to create a microporosity which reduces a thermal conductivity of the thermal barrier coating;
and wherein to generate the micro-defects and/or the nano-defects for creating the microporosity during the coating process or during the application of the thermal barrier coating, dry ice is introduced or injected into a material applied for a formation of the thermal barrier coating.

3. The process according to claim 2, wherein the component is a gas turbine component.

4. The process according to claim 2, wherein the component is a gas turbine component of an aircraft engine.

5. A process for producing a thermal barrier coating on a component, comprising the steps of:
incorporating micro-defects and/or nano-defects into the thermal barrier coating;
wherein the micro-defects and/or the nano-defects are created by introducing dry ice into a material of the thermal barrier coating.

6. The process according to claim 5, wherein the material is an oxide ceramic.

7. The process according to claim 6, wherein the dry ice is introduced into the oxide ceramic during a coating process of the oxide ceramic on the component.

8. The process according to claim 5, wherein the component is a gas turbine component.

9. The process according to claim 5, wherein the component is a gas turbine component of an aircraft engine.
